(19) United States
(12) Patent Application Publication
(10) Pub. No.: US 2026/0354070 A1
(43) Pub. Date: Nov. 5, 2026

(54) SINGULATION METHOD FOR TEMPORARY BONDED DIE-TO-CHIP TECHNIQUE

(71) Applicant: TOKYO ELECTRON LIMITED, Tokyo (JP)

(72) Inventors: Partha MUKHOPADHYAY, Oviedo, FL (US); H. Jim FULFORD, Marianna, FL (US)

(73) Assignee: TOKYO ELECTRON LIMITED, Tokyo (JP)

(21) Appl. No.: 19/197,770

(22) Filed: May 2, 2025

(51) Int. Cl. H10P 54/00

(52) U.S. Cl. CPC H10P 54/00

(57) ABSTRACT

Aspects of the present disclosure provide a singulation method. For example, the singulation method can include providing a carrier wafer bonded to a device wafer that includes a plurality of dies arranged in an array, each of the dies being surrounded by a plasma trench, a blade trench being formed between the plasma trenches of any two neighboring dies. The singulation method can also include forming a plasma trench mask to cover the dies and the blade trenches with the plasma trenches uncovered, plasma dicing the device wafer until uncovering the carrier wafer, removing the plasma trench mask, forming a blade trench mask to cover the dies and the plasma trenches with the blade trenches uncovered, blade dicing the device wafer until the carrier wafer is cut through and the dies are separated from each other, removing the blade trench mask, and releasing the carrier wafer from the device wafer.

### FIELD OF THE INVENTION

The present disclosure relates to semiconductor processing, and, in particular, to a singulation method for temporary bonded die-to-chip techniques.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In semiconductor manufacturing, temporary bonding adhesives can be used for handling thinned device wafers during various processing steps such as high dielectric deposition and through silicon via (TSV) architectures that are often employed in producing next-generation integrated circuit chips.

### SUMMARY

Aspects of the present disclosure provide a singulation method. For example, the singulation method can include providing a device wafer that is bonded to a carrier wafer. The device wafer can include a plurality of dies that are arranged in an array. Each of the dies can be surrounded by a plasma trench. A blade trench can be formed between the plasma trenches of any neighboring two of the dies. The singulation method can also include forming a plasma trench mask to cover the dies of the device wafer and the blade trenches, with the plasma trenches uncovered. The singulation method can also include plasma dicing the device wafer until uncovering at least a top surface of the carrier wafer. The singulation method can also include removing the plasma trench mask. The singulation method can also include forming a blade trench mask to cover the dies of the device wafer and the plasma trenches, with the blade trenches uncovered. The singulation method can also include blade dicing the device wafer until the carrier wafer is cut through and the dies are separated from each other, to fully singulate the dies. The singulation method can also include removing the blade trench mask. The singulation method can also include releasing the carrier wafer from the device wafer.

In an embodiment, the blade trenches can be wider than the plasma trenches. In some embodiments, the blade dicing can employ a blade that is located within the plasma trenches. In various embodiments, the blade dicing can employ a blade that is located within the blade trenches.

In an embodiment, the singulation method can further include forming an adhesive structure to bond the device wafer to the carrier wafer. For example, the adhesive structure can include a polymer adhesive structure. In some embodiments, forming the adhesive structure to bond the device wafer to the carrier wafer can include forming a carrier polymer adhesive on a frontside of the carrier wafer, forming a device polymer adhesive on a frontside of the device wafer, and bonding the device wafer to the carrier wafer by bonding the carrier polymer adhesive to the device polymer adhesive. For example, the carrier polymer adhesive can be bonded to the device polymer adhesive at room temperature. In various embodiments, the singulation method can further include baking the device wafer and the carrier wafer that are bonded to each other. In an embodiment the device polymer adhesive can be thicker than the carrier polymer adhesive. In another embodiment plasma dicing the device wafer until uncovering at least the top surface of the carrier wafer can include plasma dicing the device wafer until uncovering the carrier polymer adhesive. In some embodiments, plasma dicing the device wafer until uncovering at least the top surface of the carrier wafer can include plasma dicing the device wafer until uncovering the device polymer adhesive.

In an embodiment, the singulation method can further include forming a first oxide layer on the frontside of the device wafer prior to forming the device polymer adhesive, wherein the device polymer adhesive is formed on the first oxide layer. For example, the first oxide layer can be formed at a temperature that is low enough that the polymer adhesive structure remains unchanged. As another example, the first oxide layer can protect the frontside of the device wafer from polymer reaction.

In an embodiment, the singulation method can further include thinning the device wafer prior to forming the plasma trench mask. In another embodiment, the singulation method can further include forming a second oxide layer on the thinned device wafer.

In an embodiment, the carrier wafer can include a glass wafer. In another embodiment, the carrier wafer can include a quartz wafer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A-1C, 2A-2C, 3, 4A, 4B, 5A, 5B, 6A, 6B, 7A and 7B are cross-sectional and top-down views illustrating intermediate steps of an exemplary singulation method that involves plasma and blade dicing a semiconductor structure according to some embodiments of the present disclosure; and

FIGS. 8A, 8B, 9A and 9B are cross-sectional and top-down views illustrating intermediate steps of an exemplary singulation method that involves plasma and blade dicing a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Temporary wafer bonding is a crucial technique in semiconductor manufacturing, particularly for creating ultra-thin wafers (e.g., device wafers). The process may involve attaching a device wafer to a carrier wafer using temporary bonding adhesives. This protects the device wafer during subsequent processing steps such as back-grinding and other backside treatments that could otherwise damage or warp the device wafer. Basically, this setup allows the device wafer to withstand the stresses of thinning and subsequent processing steps, such as through-silicon via (TSV) formation, metal plating, and backside processing. Once these processes are complete, the thinned and fragile device wafers can be diced into multiple dies and then hybrid bonded (e.g., with an adhesive) to another die by pick-&-place technique. Thereafter, the adhesive is removed, releasing the processed thinned device wafer from the carrier wafer. This approach enables the creation of device wafers significantly thinner than would be possible without the added support, opening up possibilities for advanced 3D integration and miniaturization in microelectronics.

The conventional plasma dicing (or etching) cannot fully dice the transparent glass/quartz carrier wafer during the die preparation. Additionally, the scribe line between two neighboring dies is usually full of metal lines and test structures which are not possible to be etched out by plasma. Thereby blade dicing (or etching) from the frontside or the quartz side of the carrier wafer can easily damage the thinned device wafer that is temporarily bonded to the quartz carrier wafer.

According to the present disclosure, a method is proposed that can involve two-step dicing. It starts with plasma dicing (or etching) followed by blade dicing. The trench with a specific trench width removes any remaining in the scribe line. The remaining can destroy the circuitry after hybrid bonding. This method allows to dice the whole thing without damaging the thinned fragile test chip. According to the present disclosure, a method of dicing a device wafer can be developed that includes plasma and blade dicing to a thinned device wafer that is temporarily bonding to a carrier wafer, e.g., a quartz/glass carrier wafer. In an embodiment, the method can include a trench scheme to plasma etch the thinned device wafer from the front/top till the organic adhesive substances around the die dimensions. A second trench with a specific width can thereafter allow blade dicing the device wafer along the scribe line to the glass substrate of the carrier wafer in such a way that no remaining of the top device wafer is present which can hinder the fusion bonding. Finally, the glass carrier wafer and other remaining polymer adhesives can be released by cleaning.

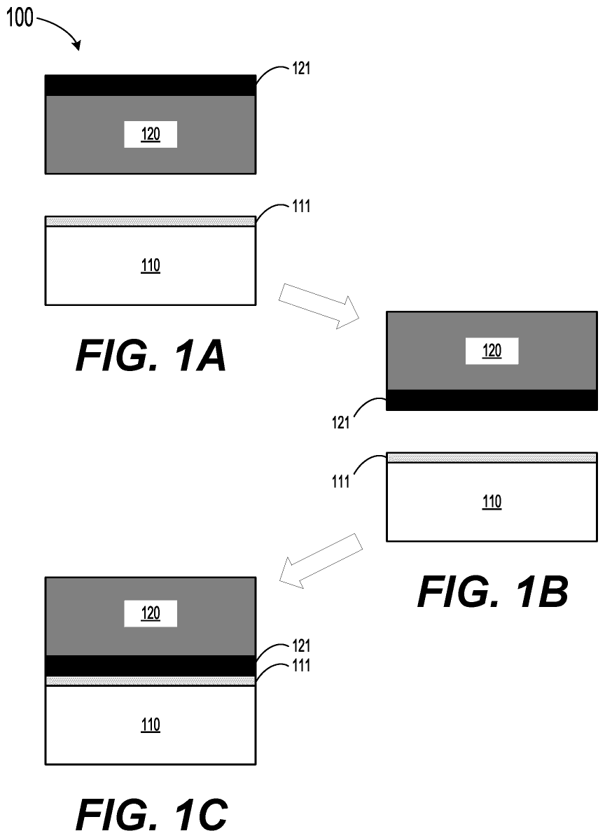

FIGS. 1A-1C, 2A-2C, 3, 4A, 4B, 5A, 5B, 6A, 6B, 7A and 7B are cross-sectional and top-down views illustrating intermediate steps of an exemplary singulation method that involves plasma and blade dicing a semiconductor structure 100 (e.g., including the device wafer).

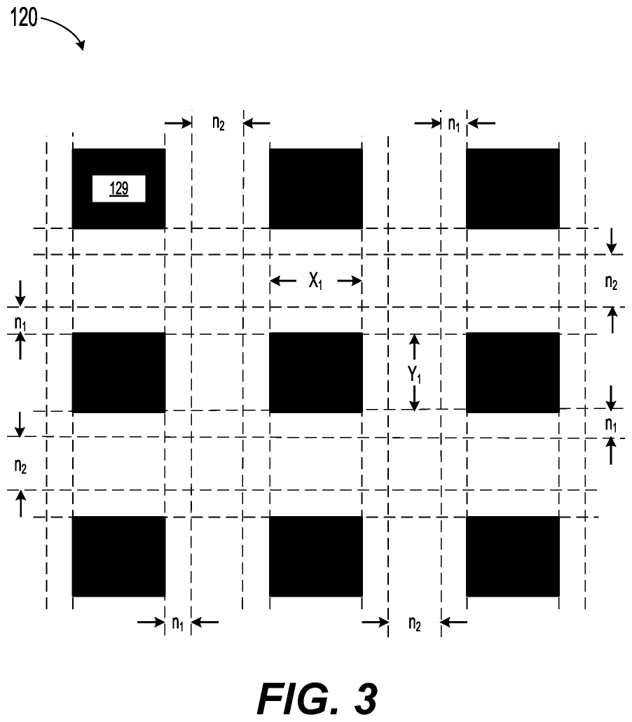

In an embodiment, the method can include providing a carrier wafer 110 and a device wafer 120 that includes a plurality of dies 129 (shown in FIG. 3) arranged in an array, and forming a carrier adhesive (or a first adhesive) (e.g., polymer) 111 and a device adhesive (or a second adhesive) (e.g., polymer) 121 on the frontsides of the carrier wafer 110 and the device wafer 120, respectively, as shown in FIG. 1A. In an embodiment, the device adhesive 121 can be thicker than the carrier adhesive 111. In another embodiment, the device adhesive 121 and the carrier adhesive 121 can include a light-sensitive adhesive, such as an ultraviolet-curable (UV-curable) polymer material. In some embodiments, the carrier wafer 110 can include a glass/quartz carrier wafer for light-sensitive adhesive removal. In various embodiments, the device wafer 120 can include a Si, Ge or SiGe device wafer. In an embodiment, the method can also include flipping over the device wafer 120 and bonding the device wafer 120 to the carrier wafer 110 (e.g., at room temperature) temporarily, as shown in FIGS. 1B and 1C. In some embodiments, the method can further include slightly baking the bonded device wafer 120 and the carrier wafer 110 to strengthen the bonding. In an embodiment, the method can further include forming (e.g., depositing) an oxide layer on the frontside of the device wafer 120 prior to forming the device adhesive 121. The oxide layer can protect the frontside of the device wafer 120 from polymer reaction and its cleaning chemicals, if any.

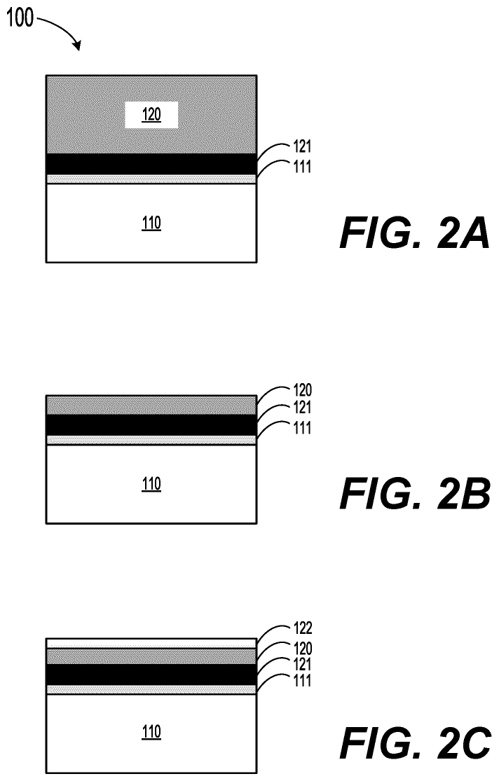

In an embodiment, the method can also include thinning (e.g., grinding followed by polishing) the backside of the (upside down) device wafer 120, as shown in FIGS. 2A and 2B. In an embodiment, the temporary bonding holds the device wafer 120 strongly so that the device wafer 120 can go back-grinding with any wafer handling. In an embodiment, the method can also include forming (e.g., depositing) an oxide layer 122 on the backside of the thinned device wafer 120, as shown in FIG. 2C. In some embodiments, the oxide layer 122 can be formed at a temperature low enough that the bonding (i.e., the polymer structure including the carrier adhesive 111 and the device adhesive 121) remains unchanged.

In an embodiment, the method can also include forming a recess plasma trench (or the width of the plasma trench) n1 (nm) around each of the dies 129 of the device wafer 120 and a blade trench (or the width of the blade trench) n2 (nm) between the plasma trenches n1 of any two neighboring dies 129, as shown in FIG. 3. In an embodiment, the blade trench n₂, which is the scribe line for blading dicing, can be far greater than the plasma trench n1, though it is shown in FIG. 3 that the blade trench n2 is slightly greater than the plasma trench n₁ for clarity. In another embodiment, the die can be X₁ (mm) in width and Y₁ (mm) in length.

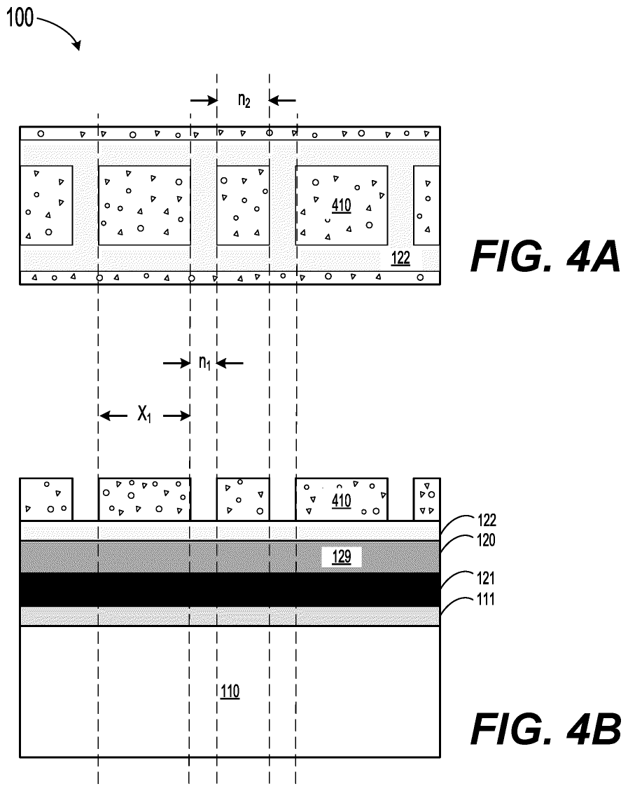

In an embodiment, the method can also include forming a plasma trench mask 410 to cover the dies 129 of the device wafer 120 and the scribe lines n₂ for plasma dicing to the device wafer 120, with the plasma trenches n₁ uncovered, as shown in FIGS. 4A and 4B.

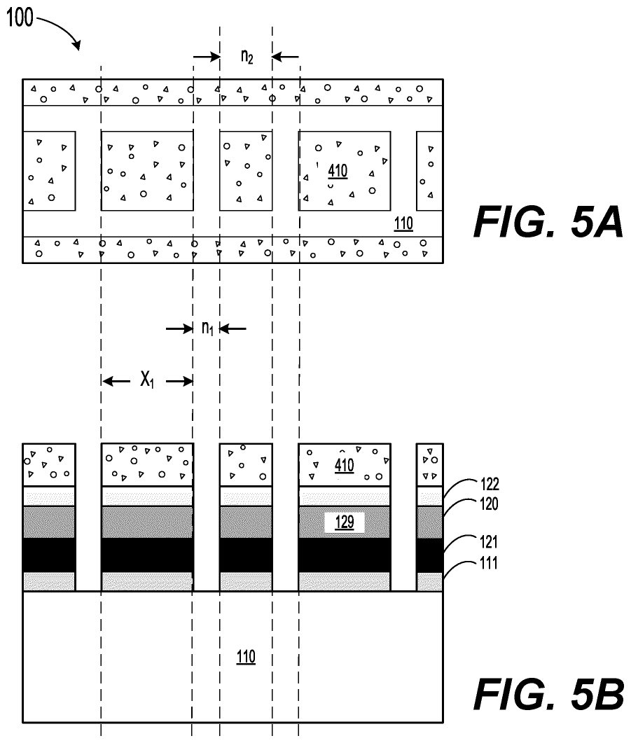

In an embodiment, the method can also include plasma etching a first portion of the thinned device wafer 120 that is not covered by the plasma trench mask 410, i.e., the plasma trench n₁, until uncovering the device adhesive 121, the carrier adhesive 111 or at least the top surface of the carrier wafer 110, as shown in FIGS. 5A and 5B. Then, the plasma trench mask 410 can be removed.

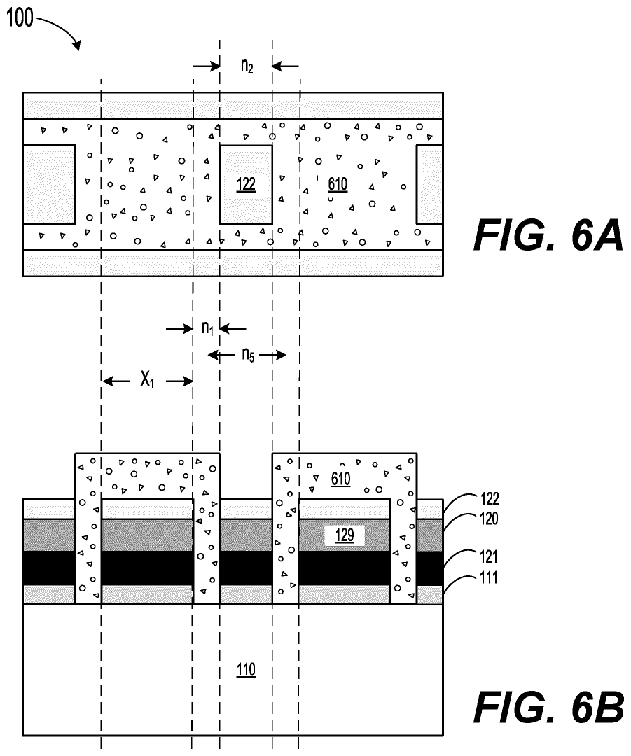

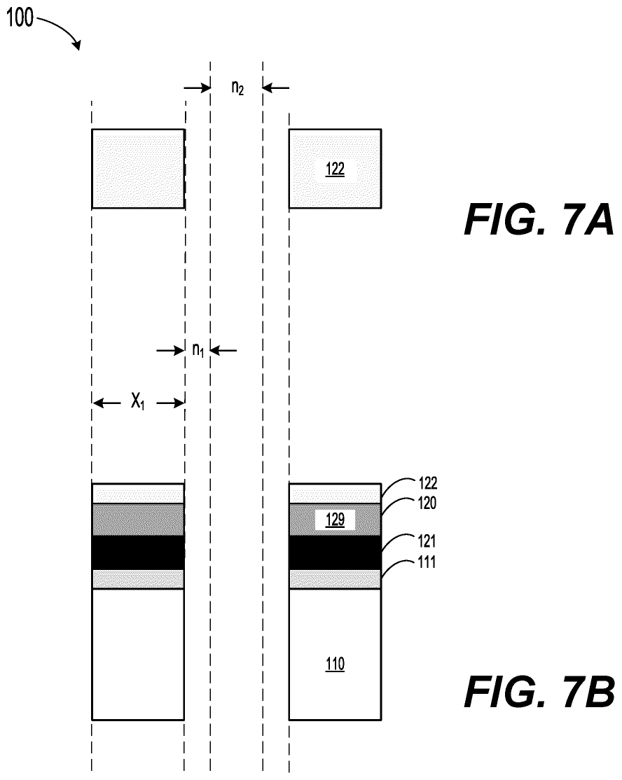

In an embodiment, the method can also include forming a blade trench mask 610 to cover the dies 129 of the device wafer 120 and the etched plasma trenches n₁, with the blade trenches n₂ uncovered, as shown in FIGS. 6A and 6B. In an embodiment, the width of a blade used for the blade dicing can be n₃, the margins of the blade can be n₄, and the width for the blade dicing can be n₅ that is equal to n₃+n₄—a space needed for blade dicing. In the example embodiment shown in FIGS. 6A, 6B, 7A and 7B, the width n₅ for the blade dicing can be greater than n₂ and less than n₂+2n₁, that is, locating the blade within the plasma trench n₁.

In an embodiment, the method can also include blade etching a second portion of the thinned device wafer 120 that is not covered by the blade trench mask 610, i.e., the blade trench n₂, with the blade located within the plasma trench n₁, until the carrier wafer 110 are cut through and the dies 129 are thus separated from each other, to fully singulate the dies 129, as shown in FIGS. 7A and 7B. Then, the blade trench mask 610 can be removed, and the carrier wafer 110, the carrier adhesive 111 and the device adhesive 121 can be released from the dies 129.

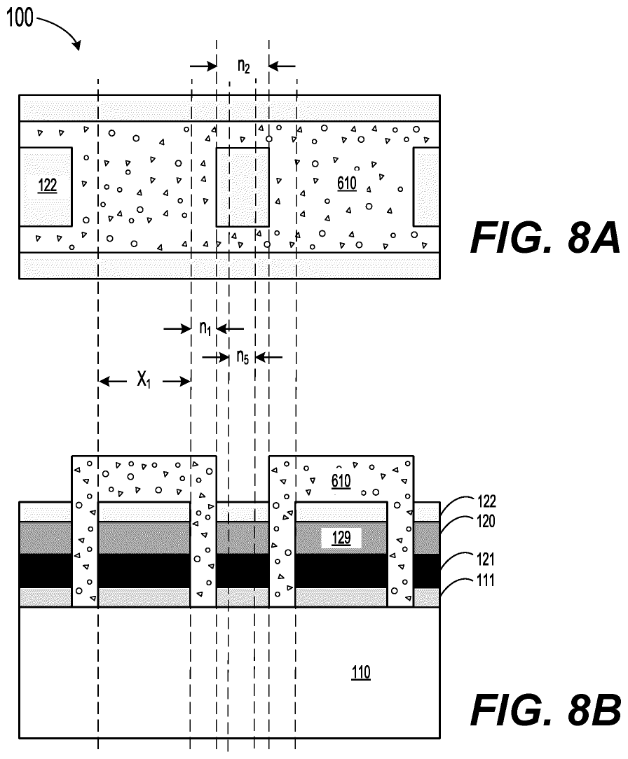

FIGS. 8A and 8B differ from FIGS. 6A and 6B in that in FIGS. 8A and 8B the width of the blade dicing n₅ is less than the width of the blade trench n2, that is, locating the blade within the blade trench n₂.

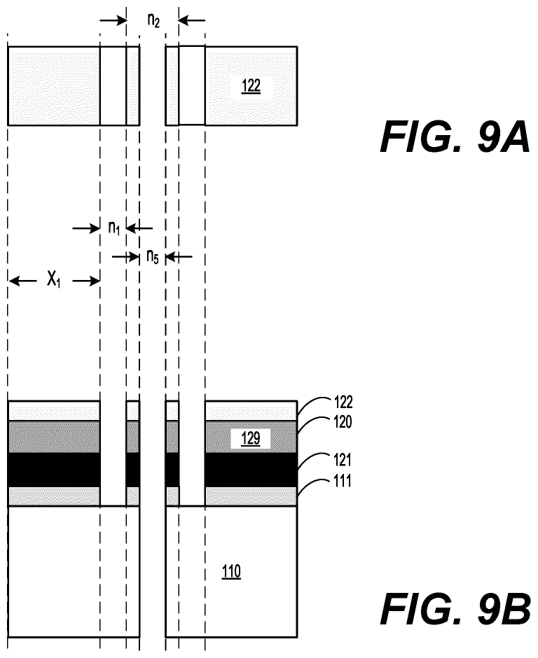

FIGS. 9A and 9B show blade dicing the second portion of the thinned device wafer 120, i.e., the blade trench n₂, with the blade located within the blade trench n₂, until the carrier wafer 110 is cut through and the dies 129 are thus separated from each other, to fully singulate the dies 129. Accordingly, there will be remaining in the scribe line n₂. This remaining would hinder the hybrid bonding.

According to the present disclosure, a method of combined dicing by plasma and blade dicing is proposed to singulate a die from a grinded and thinned device wafer that is temporarily bonded to a glass/quartz carrier wafer with polymer adhesives for pick-&-place die-to-wafer hybrid bonding without damaging the top circuitry and successfully transferring to a new substrate. In an embodiment, the method can include the design of an opening with specific widths corresponding to plasma etching followed by blade dicing along the metal-contained scribe line to remove all remaining materials in the scribe line while not touching or stressing the thinned die. The two steps dicing method with a specific width of the opening can be performed based on the width of the blade and will facilitate the singulation of the die without any remaining which can lead to failure of the hybrid bonding. The method also facilitates cost-effective solutions with less time-consuming.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A singulation method, comprising:
providing a device wafer that is bonded to a carrier wafer, the device wafer including a plurality of dies that are arranged in an array, each of the dies being surrounded by a plasma trench, a blade trench being formed between the plasma trenches of any neighboring two of the dies;
forming a plasma trench mask to cover the dies of the device wafer and the blade trenches, with the plasma trenches uncovered;
plasma dicing the device wafer until uncovering at least a top surface of the carrier wafer;
removing the plasma trench mask;
forming a blade trench mask to cover the dies of the device wafer and the plasma trenches, with the blade trenches uncovered;
blade dicing the device wafer until the carrier wafer is cut through and the dies are separated from each other, to fully singulate the dies;
removing the blade trench mask; and
releasing the carrier wafer from the device wafer.

2. The singulation method of claim 1, wherein the blade trenches are wider than the plasma trenches.

3. The singulation method of claim 1, wherein the blade dicing employs a blade that is located within the plasma trenches.

4. The singulation method of claim 1, wherein the blade dicing employs a blade that is located within the blade trenches.

5. The singulation method of claim 1, further comprising:
forming an adhesive structure to bond the device wafer to the carrier wafer.

6. The singulation method of claim 5, wherein the adhesive structure includes a polymer adhesive structure.

7. The singulation method of claim 6, wherein forming the adhesive structure to bond the device wafer to the carrier wafer includes:
forming a carrier polymer adhesive on a frontside of the carrier wafer;
forming a device polymer adhesive on a frontside of the device wafer; and
bonding the device wafer to the carrier wafer by bonding the carrier polymer adhesive to the device polymer adhesive.

8. The singulation method of claim 7, wherein the carrier polymer adhesive is bonded to the device polymer adhesive at room temperature.

9. The singulation method of claim 7, further comprising:
baking the device wafer and the carrier wafer that are bonded to each other.

10. The singulation method of claim 7, wherein the device polymer adhesive is thicker than the carrier polymer adhesive.

11. The singulation method of claim 7, wherein plasma dicing the device wafer until uncovering at least the top surface of the carrier wafer includes plasma dicing the device wafer until uncovering the carrier polymer adhesive.

12. The singulation method of claim 7, wherein plasma dicing the device wafer until uncovering at least the top surface of the carrier wafer includes plasma dicing the device wafer until uncovering the device polymer adhesive.

13. The singulation method of claim 7, further comprising:
forming a first oxide layer on the frontside of the device wafer prior to forming the device polymer adhesive,
wherein the device polymer adhesive is formed on the first oxide layer.

14. The singulation method of claim 13, wherein the first oxide layer is formed at a temperature that is low enough that the polymer adhesive structure remains unchanged.

15. The singulation method of claim 13, wherein the first oxide layer protects the frontside of the device wafer from polymer reaction.

16. The singulation method of claim 1, further comprising:
thinning the device wafer prior to forming the plasma trench mask.

17. The singulation method of claim 16, further comprising:
forming a second oxide layer on the thinned device wafer.

18. The singulation method of claim 1, wherein the carrier wafer includes a glass wafer.

19. The singulation method of claim 1, wherein the carrier wafer includes a quartz wafer.
